(19) United States
(12) Patent Application Publication
(10) Pub. No.: US 2003/0091738 A1
(43) Pub. Date: May 15, 2003

(54) Vacuum deposition method, products thereof, and devices therefor

(75) Inventors: Jian-Ping Wang, Singapore (SG); Jianzhong Shi, Singapore (SG); Tow Chong Chong, Singapore (SG)

Correspondence Address: Daniel B. Schein, BRINKS HOFER GILSON & LIONE, P.O. Box 10395, Chicago, IL, 60610, US

(73) Assignee: DATA STORAGE INSTITUTE

(21) Appl. No.: 10/179,541

(22) Filed: Jun. 24, 2002

(30) Foreign Application Priority Data
Nov. 12, 2001 (SG) 200106965-7

(51) Int. Cl. C23C 16/00; C23F 1/00

(52) U.S. Cl. 427/248.1; 427/180; 118/729; 118/730; 156/345.54; 156/345.55

(57) ABSTRACT

A method of forming at least one layer on a substrate surface by vacuum deposition of particles onto the substrate surface, the method comprising the step of moving at least part of the substrate at high speed during vacuum deposition in a first direction parallel to the substrate surface. The method reduces the amount of macroparticles in a layer or layers deposited on the substrate, and controls the microstructure and crystallographic structure of the deposited layer or layers. Also disclosed are devices for performing the method, and resulting products, for example a hard disk thin film media.

The present invention relates to a method of forming at least one layer on a substrate surface by vacuum deposition.

Vacuum deposition is a well-established art for coating substrates. Vacuum deposition methods include evaporation, sputtering, molecular beam epitaxy, metalorganic chemical vapor deposition, laser ablation, and filtered cathodic arc deposition. Although the techniques of the methods differ in some respect from one another, the fundamental process shared by these techniques involves deposition sources producing under vacuum conditions an active precursor of the film such as liberated atoms, molecules, clusters etc., and then depositing these particles on a pre-selected substrate disposed in a vacuum chamber to form the film.

It is an aim of the present invention to provide a technique for forming at least one layer by vacuum deposition by which the microstructure and crystallographic structure, and hence the physical properties, of the resulting film can be better controlled.

It is an alternative aim of the present invention to provide a technique for forming a layer by vacuum deposition by which the existence of macroparticles in the layer can be reduced or eliminated.

According to a first aspect of the present invention, there is provided a method of forming a layer on a substrate surface by vacuum deposition of particles onto the substrate surface, the method comprising the step of moving at least part of the substrate at high speed during vacuum deposition in a first direction parallel to the substrate surface.

According to another aspect of the present invention, there is provided a device for forming a layer on a substrate surface by vacuum deposition of particles onto the substrate surface, the device comprising a vacuum chamber and a motor capable of moving at least part of the substrate within the vacuum chamber at a high speed in a first direction parallel to the substrate surface or moving the precursor of the deposition with respect thereto.

The term high speed refers to a speed sufficient to generate in the particles as they hit the substrate a component of momentum in the first direction which is significant compared to the momentum already possessed by the particles before they hit the substrate surface so as to have an effect on the microstructure and the crystalographic texture of the layer being deposited on the substrate. In a preferred embodiment, the substrate is moved at a speed of no less than one tenth, further preferably no less than one half of the average speed of the particles on the first direction at the point of deposition onto the substrate surface.

This invention has particular application in the production of hard disk thin film media. Hard disk media generally comprise multiple layers, for example, overcoat, magnetic layers, underlayers, and a seedlayer. Orientation ratio is critical to hard disk thin film media because it can result in many benefits in media performance. High orientation ratio requires a large macro-anisotropy for the media along the radial and circumferential direction of a hard disk that is circular in shape. The present invention provides a direct and economical way to achieve such macro-anisotropy.

According to another aspect of the present invention, there is provided a method of forming a layer on a substrate surface by vacuum deposition of particles onto the substrate surface, the method comprising the step of rotating the substrate at a speed sufficiently high to cause all or a substantial portion of the macroparticles that may be formed on the substrate surface to be selectively thrown off the substrate surface by a centrifugal effect.

According to another aspect of the present invention, there is provided a device for forming a layer on a substrate surface by vacuum deposition of particles onto the substrate surface, the device comprising a vacuum chamber and a motor capable of rotating the substrate within the vacuum chamber at a speed sufficiently high to all or substantially all of the macroparticles that may be formed on the substrate surface to be selectively thrown off the substrate surface by a centrifugal effect.

According to a further aspect of the present invention, there is provided a device for forming a layer on a substrate surface by vacuum deposition of particles onto the substrate surface, the device comprising a vacuum chamber and a driver capable of effecting relative movement between the precursor and the substrate within the vacuum chamber at a speed sufficiently high to cause all or substantially all of the macroparticles that may be formed on the substrate surface to be selectively thrown off the substrate surface by a centrifugal effect.

Alternatively, the driver comprises a motor for rotating the substrate within the vacuum chamber at a speed sufficiently high to cause at least part of the macroparticles that may be formed on the substrate surface to be selectively thrown off the substrate surface by a centrifugal effect.

Alternatively, the driver comprises a motor for rotating the precursor within the vacuum chamber at a speed sufficiently high to cause at least part of the macroparticles that may be formed on the substrate surface to be selectively thrown off the substrate surface by a centrifugal effect.

The term “macroparticle” refers to particles having a diameter of at least micrometer dimensions, e.g., 1 μm to 10 μm, at least sub-micrometer dimensions, e.g., 0.1 μm to 1 μm, or at least deep sub-micrometer dimensions, e.g., 0.01 μm to 0.1 μm.

Embodiments of the present invention are described hereunder, by way of example only, with reference to the accompanying drawings, in which:

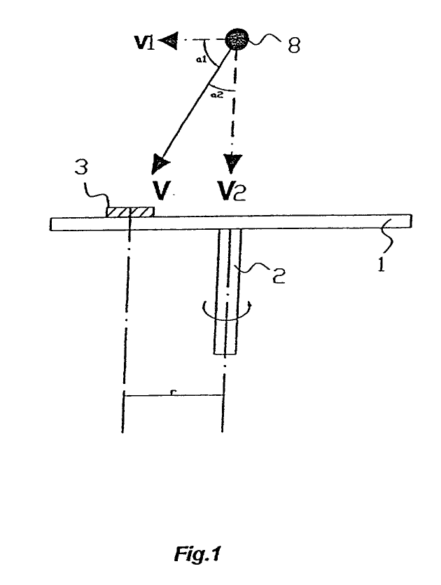

FIG. 1 is a schematic diagram showing the principle of vacuum deposition.

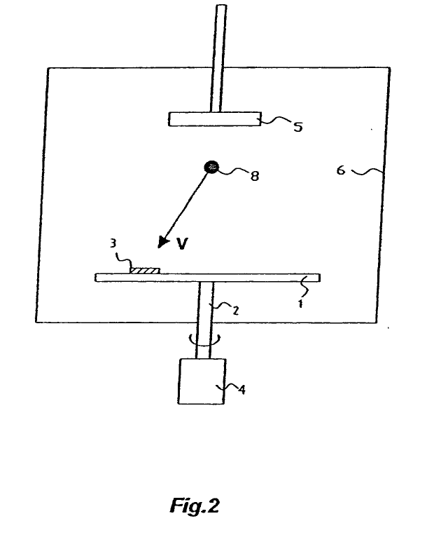

FIG. 2 is a cross-sectional view of a first alternative embodiment of a device for carrying out the present invention.

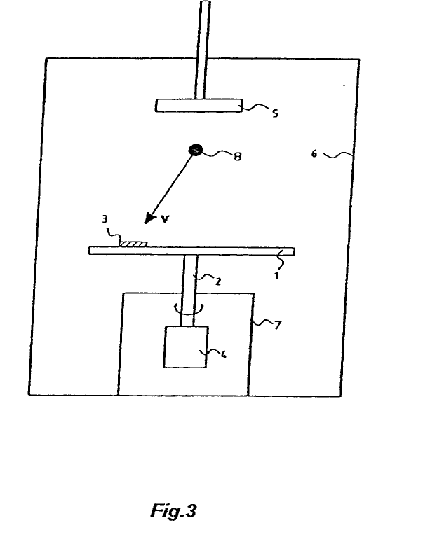

FIG. 3 is a cross-sectional view of a second alternative embodiment of a device for carrying out the present invention.

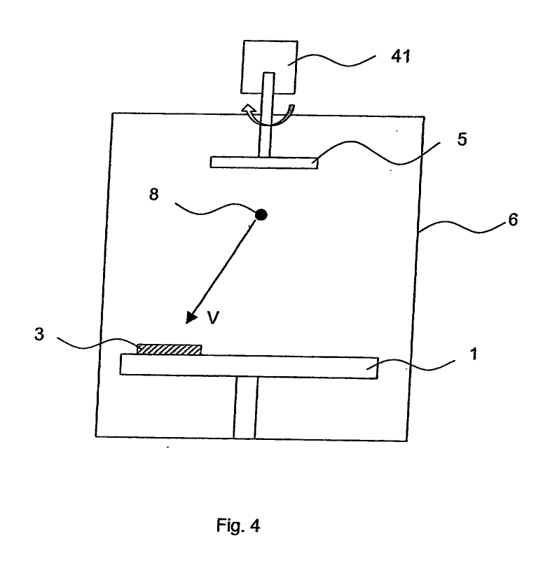

FIG. 4 is a cross-sectional view of a third alternative embodiment of a device for carrying out the present invention.

A cross-sectional view of a device for carrying out the present invention is illustrated in FIG. 2. A substrate holder 1 is positioned in the bottom of a vacuum chamber enclosed by a chamber housing 6 which can be evacuated by suitable vacuum pumping means and can be back-filled by gas-supplying component with a suitable gas (not shown). The vacuum chamber preferably has a cylindrical or rectangular shape. Outside the chamber housing 6 is a high-speed rotational motor 4, whose rate of rotation is tunable. On the substrate holder 1 is securely mounted a substrate 3. Between the substrate holder 1 and the motor 4 is an axis 2, whose upper end is connected to the center of the substrate holder, and lower end is connected the motor. The axis 2 extends into the vacuum chamber housing 6 via a feedthrough (not shown) so as to provide a rotational seal. A film precursor 5 is provided in the upper part of the chamber. In the case of sputtering deposition, for example, the precursor is a target. During deposition, the precursor 5 is activated and particles 8 such as atoms or molecules or clusters are liberated from the precursor 5 and move with a kinetic energy to the rotating substrate 3. On the substrate surface, the particle 8 has both an initial speed and a circumferential speed. The former is determined by the activating process and the transferring process within the vacuum. The latter is determined by the speed of the substrate, which can be controlled by tuning the rate of rotation of the motor. Particles deposited on the substrate holder form a film by nucleating and nuclear growth.

Another device for carrying out the present invention is illustrated in FIG. 3. It is similar to the device shown in FIG. 2. It differs in that the motor in FIG. 3 is in the vacuum chamber 6. The motor is a vacuum-compatible motor to allow it to function under vacuum conditions. A frame 7 is used for supporting the weight of the substrate holder 1, substrate 3 and the motor 4 and the axis 2.

In a preferred embodiment of the method of the present invention, the substrate holder is rotated such that the substrate is moved at a speed no less than one tenth, preferably no less than one half of the average speed of the particles in a direction parallel to the substrate surface at the point of deposition onto the substrate surface. Non-limiting examples of suitable substrates for use with the present invention include glass, glass-ceramic, aluminum, titanium or silicon.

An alternative device for carrying out the present invention is illustrated in FIG. 4. it is similar to the device shown in FIG. 2. It defers in that the substrate 3 is fixed but the precursor 5 is rotated by a motor 41. During deposition, the precursor 5 is activated and at the same time rotating. Particles 8 such as atom or molecule or cluster are liberated from the rotating precursor 5. Since the precursor is rotating, the particles 8 have both an initial speed and a circumferential speed. The former is determined by the activating process and the transferring process within the vacuum. The latter is determined by the rotating of the precursor which can be controlled by tuning the rate of rotation of the motor 41. Particles deposited on the substrate form a film by nucleating and nuclear growth.

The average speed of the particles in a direction parallel to the substrate surface at the point of deposition onto the substrate surface can be determined as follows with reference to FIG. 1.

FIG. 1 shows the principle of vacuum deposition. A particle 8 (an atom, molecule or cluster), which has been activated from its precursor has a kinetic energy with a speed of V. On the substrate holder 1 is securely mounted a substrate 3 at a distance r from the axis of rotation of the substrate holder 1. The direction of the particle speed V has a tilt angle α2 with respect to a direction normal to the plane of the substrate holder or substrate rather than being parallel to it. The component V1 of the particle's velocity in a direction parallel to the substrate surface is given by equation (1)

V1=V sin α2 (1)

The energy of the particle, E, is given by equation (2)

E=mV²/2 (2)

where m is the particle mass.

Combining equation (1) and (2), the average speed of the particle V1 in a direction parallel to the substrate surface is represented as:

$$V1 = \sqrt{\frac{2 E}{m}} sin α2 \qquad ( 3 )$$

The particle 8 may for example be a Cu atom with m=63.5×10³/(6.02×10²³) kg and α2=10°. Taking sputtering deposition as an example, the average energy of a Cu atom at the target surface is about 2 eV (Reference is made to Stuart and Wehner, 3. Appl.Phys. 35,1819 (1964)). Before the particle arrives at the substrate surface, it typically undergoes a series of collision with atoms of the working gas, such as Ar, resulting in a loss of kinetic energy for the particle. The average energy of a Cu atom when it arrives at the substrate surface is about E=0.04 eV (Reference is made to William D. Westwood, Sputter Deposition (1998)).

The latter of these values, E, together with the mass and angle of deposition, α2 can be used to determine the average speed of the particle in a direction parallel to the substrate surface at the point of deposition onto the substrate surface.

The speed at which the substrate holder should be rotated can be calculated as follows.

The tangential speed, Vr of the substrate is given by equation (4) below.

Vr=2πr. S/60 (4)

Where r is the distance between the substrate and the rotation axis 2, and S is the number of revolutions per minute.

As mentioned above, in a preferred embodiment, the tangential speed of the substrate should be no less than one half of the average speed of the particles in a direction parallel to the substrate surface at the point of deposition. In the case of the deposition of copper atoms by sputter deposition mentioned above onto a substrate located at 4 cm from the rotation axis of the substrate holder, the rate of rotation of the substrate holder would be no less than 7200 revolutions per minute (r.p.m.). In a preferred embodiment, the substrate holder rotates the substrate at a rate of at least about 1,000 r.p.m., and most preferably at least about 7,000 r.p.m.

The process of rotating the substrate at low speeds, e.g., less than 100 r.p.m., during vacuum deposition for achieving good uniformity of film thickness has been carried out previously. The present invention involves rotation of the substrate at much higher speeds to control the microstructure fabrication and hence the physical properties of the resulting film.

Although the present invention has been described in terms of the presently preferred embodiments, it is to be understood that such disclosure is not to be interpreted as limiting. Various alterations and modifications will no doubt become apparent to those skilled in the art after reading the above disclosure. Accordingly, it is intended that the appended claims be interpreted as covering all alterations and modifications as fall within the true spirit and scope of the invention.

1. A method of forming a layer on a substrate surface by vacuum deposition of particles onto the substrate surface, the method comprising the step of moving at least part of the substrate at high speed during vacuum deposition in a first direction parallel to the substrate surface.

2. The method of claim 1, wherein at least part of the substrate is moved at a speed no less than one tenth of the average speed of the particles in the first direction at the point of deposition onto the substrate surface.

3. The method of claim 1, wherein the substrate is moved by rotating the substrate about an axis perpendicular to the substrate surface.

4. The method of claim 1, wherein the vacuum deposition is carried out by one or more techniques selected from the group comprised of evaporation, sputtering, molecular beam epitaxy, metalloorganic chemical vapour deposition, laser ablation, and filtered cathodic arc deposition.

5. The method of claim 1, wherein the substrate is selected from the group consisting of glass, glass-ceramic, aluminium, titanium or silicon.

6. A device for forming a layer on a substrate surface by vacuum deposition of particles onto the substrate surface, the device comprising a vacuum chamber and a motor capable of moving at least part of the substrate within the vacuum chamber at a high speed in a first direction parallel to the substrate surface.

7. The device of claim 6, wherein the motor is capable of moving at least part of the substrate at a speed of no less than about one tenth of the average speed of the particles in the first direction at the point of deposition onto the substrate surface.

8. The device of claim 6, wherein the motor is capable of rotating the substrate within the vacuum chamber at high speed about an axis perpendicular to the plane of the substrate surface.

9. The device of claim 8, wherein the motor is capable of rotating the substrate at a speed of at least 1,000 revolutions per minute.

10. The device of claim 8, wherein the motor is located outside the vacuum chamber.

11. The device of claim 8, wherein the motor is located inside the vacuum chamber.

12. The device of claim 10, wherein the motor is a speed-tunable motor.

13. The device of claim 11, wherein the motor is a speed-tunable motor.

14. The device of claim 6, wherein the vacuum chamber has a cylindrical or rectangular shape.

15. A method of forming a layer on a substrate surface by vacuum deposition of particles onto the substrate surface, the method comprising the step of rotating the substrate at a speed sufficiently high to cause at least part of the macroparticles that may be formed on the substrate surface to be selectively thrown off the substrate surface by a centrifugal effect.

16. A device for forming a layer on a substrate surface by vacuum deposition of particles onto the substrate surface, the device comprising a vacuum chamber and a motor capable of rotating the substrate within the vacuum chamber at a speed sufficiently high to cause at least part of the macroparticles that may be formed on the substrate surface to be selectively thrown off the substrate surface by a centrifugal effect.

17. A device for forming a layer on a substrate surface by vacuum deposition of particles onto the substrate surface, the device comprising:
a vacuum chamber;
a precursor for liberating the particles for deposition, and
a driver for effecting relative movements between the precursor and the substrate at a speed sufficiently high to cause at least part of the macroparticles that may be formed on the substrate surface to be selectively thrown off the substrate surface by a centrifugal effect.

18. The device of claim 17, wherein the driver comprises a motor for rotating the substrate within the vacuum chamber at a speed sufficiently high to cause at least part of the macroparticles that may be formed on the substrate surface to be selectively thrown off the substrate surface by a centrifugal effect.

19. The device of claim 17, wherein the driver comprises a motor for rotating the precursor within the vacuum chamber at a speed sufficiently high to cause at least a part of the macroparticles that may be formed on the substrate surface to be selectively thrown off the substrate surface by a centrifugal effect.

20. A substrate with a layer created by the process of claim 1.

21. The substrate of claim 20, wherein said substrate is a hard disk thin film media.

22. A hard disk media, comprising at least one layer selected from the group consisting of a magnetic layer, an underlayer, and a seedlayer, wherein at least one layer, wherein at least one layer is formed by the method of claim 1.

23. A hard disk media, comprising at least one layer selected from the group consisting of a magnetic layer, an underlayer, and a seedlayer, wherein at least one layer, wherein at least one layer is formed using the device of claim 6.
